(19) United States
(12) Patent Application Publication
(10) Pub. No.: US 2011/0120556 A1
(43) Pub. Date: May 26, 2011

(54) Thin-Film Photovoltaic Cell

(75) Inventors: Yu-Ting LIN, Hsinchu City (TW); Shih-Che Huang, Chiayi City (TW); Wen-Kai Hsu, Zhubei City (TW)

(73) Assignee: Du Pont Apollo Limited, Hong Kong (HK)

(21) Appl. No.: 12/951,063

(22) Filed: Nov. 21, 2010

Related U.S. Application Data
(60) Provisional application No. 61/263,398, filed on Nov. 22, 2009.

(51) Int. Cl. H01L 31/0232

(52) U.S. Cl. 136/259

(57) ABSTRACT

Micro-protrusions, in micron-meter scale, are produced on a surface of the photovoltaic cell to produce scattering effect and multiple reflecting effect of incident light.

### RELATED APPLICATIONS

This application claims priority to U.S. Provisional Application Ser. No. 61/263,398, filed Nov. 22, 2009, which is herein incorporated by reference.

### BACKGROUND

1. Technical Field

The disclosure relates to a thin-film photovoltaic cell.

2. Description of Related Art

How to increase the photoelectric conversion efficiency is always an important issue in photovoltaic system. One way is to enhance the light trapping. Light trapping is trapping light inside a semiconductor material by refracting and reflecting the light at critical angles. Trapped light will travel further in the semiconductor material to greatly increase the light absorption probability and hence the probability of producing charge carriers.

### SUMMARY

According to an embodiment, a thin-film photovoltaic cell of the superstrate-type is provided. The thin-film photovoltaic cell sequentially comprises a transparent substrate, a conformal transparent conductive oxide layer, a conformal semiconductor layer, and a conformal metal layer. Micro-protrusions are disposed on the surface of the transparent substrate or the transparent conductive oxide layer. The height, width, and interval of the micro-protrusion are larger than ten times of incident light's wavelength and smaller than the width of the photovoltaic cell.

According to another embodiment, a thin-film photovoltaic cell of the substrate-type is provided. The thin-film photovoltaic cell sequentially comprises a metal substrate, a conformal semiconductor layer, and a conformal transparent conductive oxide layer. Micro-protrusions are disposed on the surface of the metal substrate. The height, width, and interval of the micro-protrusion are larger than ten times of incident light's wavelength and smaller than the width of the photovoltaic cell.

### BRIEF DESCRIPTION OF THE DRAWINGS

FIG. 1 is a cross-sectional diagram of conventional thin-film photovoltaic cells having the superstrate-type structure.

FIG. 2A is a perspective view of the surface of the photovoltaic module according to an embodiment.

FIG. 2B is a vertical view of a photovoltaic module according to another embodiment.

FIG. 3A is a cross-sectional view of photovoltaic cells having the superstrate-type structure according to another embodiment.

FIG. 3B is a cross-sectional view of photovoltaic cells having the superstrate-type structure according to another embodiment.

FIG. 3C is a cross-sectional view of photovoltaic cells having the substrate-type structure according to another embodiment.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

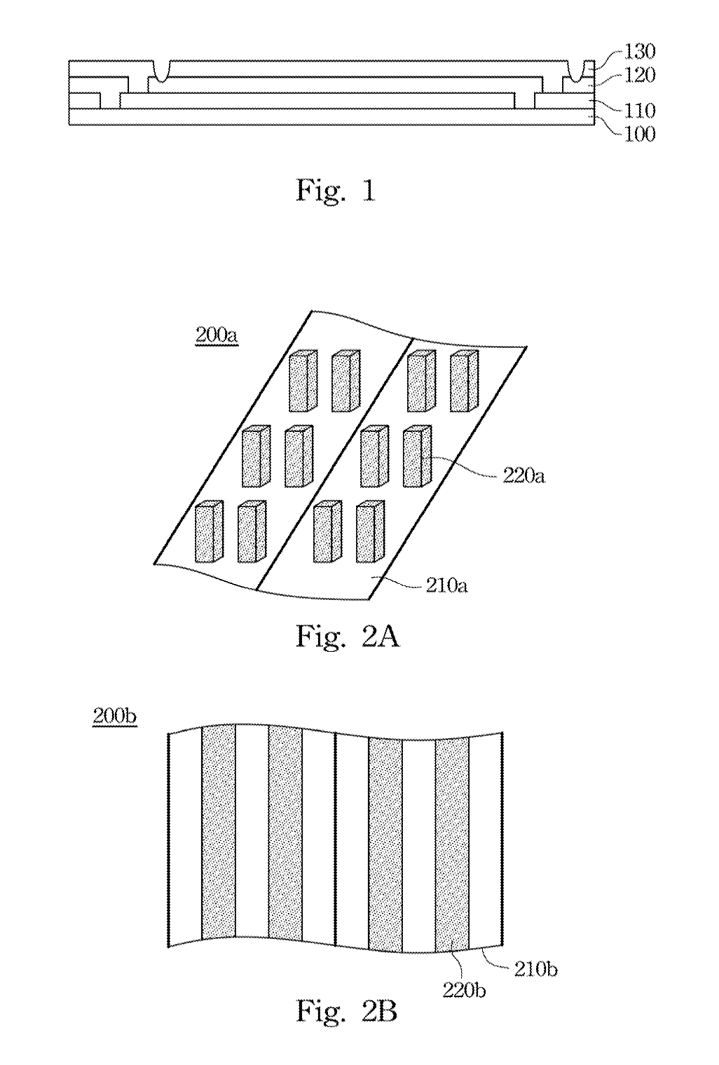

FIG. 1 is a cross-sectional diagram of conventional thin-film photovoltaic cells having the superstrate-type structure. In FIG. 1, a transparent conductive oxide (TCO) layer 110, a semiconductor layer 120, and a metal layer 130 are sequentially formed on a transparent substrate 100, and the transparent substrate 100 is the entering site of the incident light. In FIG. 1, the top surface of the TCO layer 110 is uneven in the nanometer range to scatter the incident light. Therefore, the incident angle of the incident light is changed when the incident light enters the semiconductor layer 120. Eventually, the light path in the semiconductor layer 120 can be increased to increase the light absorption probability by the semiconductor layer 120.

However, the light scattering percentage of the incident light varies with the various wavelengths of the incident light. That means, the photoelectric conversion efficiency of the photovoltaic cells is varied with the wavelength of incident light.

Accordingly, a photovoltaic cell having invariant photoelectric conversion efficiency is provided. Micro-protrusions, in micron-meter scale, are produced on a surface of the photovoltaic cell to produce scattering effect and multiple reflecting effect of incident light. According to an embodiment, the height, width, and interval of the micro-protrusions are larger than 10 times of the wavelength of the incident light and smaller than the cell width of a photovoltaic cell. Since the height, width, and interval of the micro-protrusions are larger than about 10 times of the wavelength of the incident light, the light scattering percentage caused by the micro-protrusions is not varied with the incident light's wavelength. For example, the height, width, and interval of the micro-protrusions can be 0.1-10 μm, 0.1-10 μm, and 0.1-20 μm, respectively.

FIG. 2A is a perspective view of the surface of the photovoltaic module according to an embodiment. In FIG. 2A, a photovoltaic module 200a has many photovoltaic cells 210a. On surfaces of the photovoltaic cells 210a, there are many micro-protrusions 220a formed thereon and arrayed in 2-dimensions. The shape of the micro-protrusions viewed from top can be various shapes, such as square, hexagon, circle, or any other suitable shape, but not to limit the scope of the invention.

FIG. 28 is a vertical view of a photovoltaic module according to another embodiment. In FIG. 2B, a photovoltaic module 200b also has many photovoltaic cells 210b. However, the micro-protrusions 220b are strip-like and parallel arrayed.

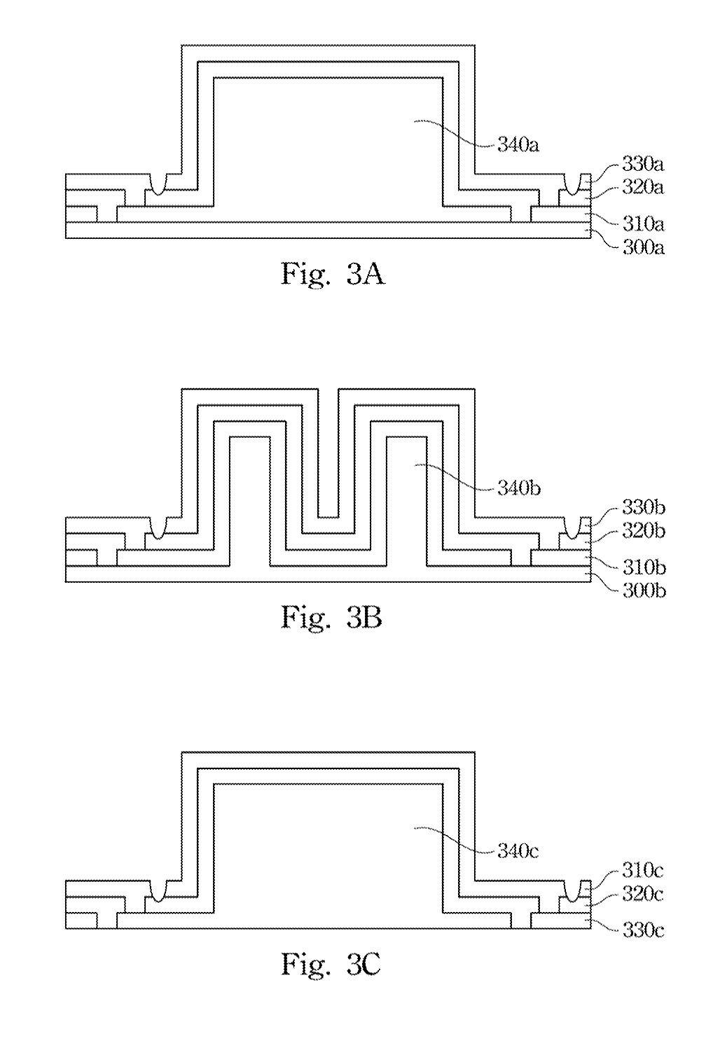

FIG. 3A is a cross-sectional view of photovoltaic cells having the superstrate-type structure according to another embodiment. In FIG. 3A, a TCO layer 310a, a semiconductor layer 320a, and a metal layer 330a are sequentially formed on a transparent substrate 300a. In the above structure, the TCO layer 320a is processed to form micro-protrusions 340a, and the semiconductor layer 320a and the metal layer 330a conformally cover the TCO layer 320a. The entering site for the incident light in FIG. 3A is the transparent substrate 310a.

FIG. 3B is a cross-sectional view of photovoltaic cells having the superstrate-type structure according to another embodiment. The structure in FIG. 3B is similar to FIG. 3A, a TCO layer 310b, a semiconductor layer 320b, and a metal layer 330b are sequentially formed on a transparent substrate 300b. However, it is the transparent substrate 300b, not the TCO layer 310b, to be processed to form micro-protrusions 340b. The entering site for the incident light in FIG. 3B is the transparent substrate 310b.

FIG. 3C is a cross-sectional view of photovoltaic cells having the substrate-type structure according to another embodiment. In FIG. 3C, a semiconductor layer 320c and a TCO layer 310c are sequentially formed on the metal substrate 330c. The metal substrate 330c is processed to form the micro-protrusions 340c. The entering site for the incident light in FIG. 3C is the TCO layer 310c.

The thickness of the TCO layer 310a, 310b, and 310c can be 0.1-3 μm, for example. The material of the TCO layer 310a, 310b, and 310c can be a metal oxide or a complex metal oxide. The metal oxides can be PbO₂, CdO, Tl₂O₃, Ga₂O₃, ZnPb₂O₆, CdIn₂O₄, MgIn₂O₄, ZnGaO₄, AgSbO₃, CuAlO₂, CuGaO₂, or CdO—GeO₂, for example. The complex metal oxide can be AZO (ZnO:Al), GZO (ZnO:Ga), ATO (SnO₂:Sb), FTO (SnO₂:F), ITO (In₂O₃:Sn), or BaTiO₃.

The material of the semiconductor layer 320a, 320b, and 320c above can be amorphous silicon, poly silicon, CdTe, or CIGS, for example.

The material of the metal layer 330a, 330b, and 330c above can be Al, Ag, Ti, or Cu, for example.

The method of forming the micro-protrusions 340a, 340b, and 340c above can be any available methods. According to an embodiment, photolithography and etching process can be used to form the micro-protrusions above. According to another embodiment, roller printing can be used to form the micro-protrusions, too.

For example, if the micro-protrusions 340a in FIG. 3A are formed by roller printing, the etchant cream coated on the roller can be acid or base, depending to on the material of the TCO layer. The acid can be H₃PO₄, HCl, CH₃COOH, HNO₃, or H₂SO₄, for example. The base can be NaOH, KOH, Na₂CO₃, or NH₃.

Other parameters of the roller printing, including conveyer speed, roller's rolling speed, pressing depth of the roller, etching temperature, cleaning temperature, and drying temperature, are listed in the table below.

| parameters | range | |
|---|---|---|
| conveyer speed | 0.5-6 | m/s |
| roller's rolling speed | 10-300 | rpm |
| pressing depth of the roller | 0-2 | mm |
| etching temperature | 25-60° | C. |
| cleaning temperature | 25-30° | C. |
| drying temperature | 60° | C. |

All the features disclosed in this specification (including any accompanying claims, abstract, and drawings) may be replaced by alternative features serving the same, equivalent or similar purpose, unless expressly stated otherwise. Thus, unless expressly stated otherwise, each feature disclosed is one example only of a generic series of equivalent or similar features.

What is claimed is:

1. A thin-film photovoltaic cell, comprising:
a transparent substrate having micro-protrusions thereon, wherein the height, width, and interval of the micro-protrusion are larger than ten times of incident light's wavelength and smaller than the width of the photovoltaic cell;
a conformal transparent conductive oxide layer on the transparent substrate;
a conformal semiconductor layer on the transparent conductive oxide to layer; and
a conformal metal layer on the semiconductor layer.

2. The thin-film photovoltaic cell of claim 1, wherein the height, width, and interval of the micro-protrusions are 0.1-10 μm, 0.1-10 μm, and 0.1-20 μm, respectively.

3. A thin-film photovoltaic cell, comprising:
a transparent substrate;
a transparent conductive oxide layer having micro-protrusions thereon, wherein the height, width, and interval of the micro-protrusion are larger than ten times of incident light's wavelength and smaller than the width of the photovoltaic cell; and
a conformal semiconductor layer on the transparent conductive oxide layer; and
a conformal metal layer on the semiconductor layer.

4. The thin-film photovoltaic cell of claim 3, wherein the height, width, and interval of the micro-protrusions are 0.1-10 μm, 0.1-10 μm, and 0.1-20 μm, respectively.

5. A thin-film photovoltaic cell, comprising:
a metal substrate having micro-protrusions thereon, wherein the height, width, and interval of the micro-protrusions are larger than ten times of incident light's wavelength and smaller than the width of the photovoltaic cell; and
a conformal semiconductor layer on the metal substrate; and
a conformal transparent conductive oxide layer on the semiconductor layer.

6. The thin-film photovoltaic cell of claim 5, wherein the height, width, and interval of the micro-protrusions are 0.1-10 μm, 0.1-10 μm, and 0.1-20 μm, respectively.
